(19) United States
(12) Patent Application Publication
(10) Pub. No.: US 2025/0253616 A1
(43) Pub. Date: Aug. 7, 2025

(54) INTEGRATED LOCAL HEATER FOR ELECTRO-ABSORPTION MODULATED LASER

(71) Applicant: MELLANOX TECHNOLOGIES, LTD., Yokneam (IL)

(72) Inventors: Uziel Koren, Herzliya (IL); Oren Steinberg, Tal Shahar (IL); Moshe Oron, Rehovot (IL); Isabelle Cestier, Haifa (IL); Elad Mentovich, Tel Aviv (IL); Timothy De Keulenaer, Ghent (BE); Jochem Verbist, Edegem (BE)

(21) Appl. No.: 18/429,797

(22) Filed: Feb. 1, 2024

(51) Int. Cl. H01S 5/026; H01S 5/024

(52) U.S. Cl. CPC H01S 5/0265; H01S 5/02453; H01S 5/02476

(57) ABSTRACT

Systems and methods are directed localized heating for a modulator incorporated into an electro-absorption modulated laser (EML). A heater may be positioned proximate one or more portions of the modulator to apply heat energy to the modulator responsive to an input. The heater may be configured to apply a dissipation of heat so that the modulator operates within a selected temperature range. The modulator and/or the heater may be thermally insulated, at least in part, from a substrate associated with the EML by one or more low thermal conductivity layers arranged between the modulator and a substrate of the EML.

### TECHNICAL FIELD

At least one embodiment pertains to providing heat energy to one or more components of a semiconductor device, and particularly to providing heat energy using resistive heating to maintain one or more components within an operational temperature range.

### BACKGROUND

As data communication demands increase in both volume and speed, fiber optics have become an increasingly popular communication medium. The use of fiber optics may incorporate electro-absorption modulators (EAMs) and electro-absorption modulated lasers (EMLs) that modulate an optical beam to encode data into a data stream. As temperature changes, efficiency of the EMLs may decrease. The increase in data communication volumes is built on data centers that may include hundreds or thousands of EMLs, and during operation, ambient temperatures within the data center may fluctuate. It may be cost prohibitive to cool the data centers or individual components in order to maintain a desired operating temperature, and as a result, EML efficiencies are often lost during certain operational periods.

### BRIEF DESCRIPTION OF THE DRAWINGS

Various embodiments in accordance with the present disclosure will be described with reference to the drawings, in which:

FIG. 1 illustrates a top view of an example electro-absorption modulated laser (EML) with an integrated heater, in accordance with at least one embodiment;

FIG. 2A illustrates a cross-sectional view, taken along line 2A-2A, of an example modulator and integrated heater, in accordance with at least one embodiment;

FIG. 2B illustrates a cross-sectional view, taken along line 2B-2B, of an example laser, in accordance with at least one embodiment;

FIG. 3 illustrates a top view of a segmented traveling wave EAM with an integrated segmented heater, in accordance with at least one embodiment;

FIG. 4 illustrates a top view of a differential drive EML with an integrated heater, in accordance with at least one embodiment.

FIG. 5A illustrates a cross section 5A-5A view of a differential EML, in accordance with at least one embodiment;

FIG. 5B illustrates a cross section 5B-5B view of a differential EML, in accordance with at least one embodiment;

FIG. 5C illustrates a cross section 5C-5C view of a differential EML, in accordance with at least one embodiment;

FIG. 6 illustrates an example process for applying an electrical power dissipation to a heater, in accordance with at least one embodiment;

FIG. 7 illustrates an example process for applying an electrical power dissipation to a heater, in accordance with at least one embodiment;

FIG. 8 illustrates an example process for applying an electrical power dissipation to a heater, in accordance with at least one embodiment; and

FIG. 9 illustrates a computer system, according to at least one embodiment.

### DETAILED DESCRIPTION

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

When introducing elements of various embodiments of the present disclosure, the articles “a”, “an”, “the”, and “said” are intended to mean that there are one or more of the elements. The terms “comprising”, “including”, and “having” are intended to be inclusive and mean that there may be additional elements other than the listed elements. Any examples of operating parameters and/or environmental conditions are not exclusive of other parameters/conditions of the disclosed embodiments. Additionally, it should be understood that references to “one embodiment”, “an embodiment”, “certain embodiments”, or “other embodiments” of the present disclosure are not intended to be interpreted as excluding the existence of additional embodiments that also incorporate the recited features. Furthermore, reference to terms such as “above”, “below”, “upper”, “lower”, “side”, “front”, “back”, or other terms regarding orientation or direction are made with reference to the illustrated embodiments and are not intended to be limiting or exclude other orientations or directions. It should be further appreciated that terms such as approximately or substantially may indicate +/−10 percent.

Approaches in accordance with various embodiments of the disclosure are directed toward localized heating for an electro-absorption modulator (EAM) incorporated in an electro-absorption modulated laser (EML) integrated device. EMLs are important components for optical links in data centers. A data center may include thousands of EMLs for data transmission, and lean power consumption is important for overall power consumption of the data center. EMLs are composed of a laser and an associated modulator, which are both integrated on a common chip. Typically, the wavelength of the laser and the characteristic wavelength of the modulator depend on temperature but shift with temperature at different rates. In a data center, the ambient temperature range may be relatively large (e.g., 20-80 degrees Celsius (° C. or deg C.)), which may cause inefficiencies in operation by trying to operate the modulator at temperatures outside of its optimized range. Traditional approaches try to cool the EML chip, in order to keep it at a constant temperature, but adding cooling is expensive and energy-intensive. Systems and methods of the present disclosure are directed toward power-efficient, localized heating of the modulator to maintain the modulator within a smaller temperature range. Because it is undesirable to heat the laser, the localized heating may be configured so that heating of the modulator does not significantly affect the laser. Examples of the thermal management methods and chip design details that can produce this performance are described herein.

Systems and methods of the present disclosure may incorporate one or more heating devices onto a chip that includes both a modulator and a laser. These components may be located on a common substrate, with the laser being configured to generate light and the modulator receiving the light and modulating the intensity of the light. Various embodiments may include a heat generating unit (e.g., a heat generating element, a heater, etc.), which may be, but is not limited to, a resistive heater, that is closely located (e.g., positioned proximate, positioned within a threshold distance, etc.) with respect to the modulator. In operation, the heat generating unit may be used to maintain the modulator within a desired temperature range. The optimized operation of the modulator may be within the desired range, which may be smaller than the large range of the ambient temperature of the data center. Accordingly, systems and methods of the present disclosure may provide for efficient heating of the modulator to reduce the wide operating range that would be present if the modulator were to operate at the ambient data center temperature and to also provide for lower cost, more efficient operations when compared to cooling the EML.

The efficiency of a heating device is inversely proportional to the heater power dissipation needed to raise the modulator temperature by one degree C. To achieve high heater efficiency, various embodiments of the present disclosure may incorporate one or more layers between one or more components of the modulator and an underlying substrate. By way of non-limiting example, a layer may be included with a low thermal conductivity that underlies a modulator region and extends between at least the modulator and the substrate. In at least one embodiment, the one or more layers may correspond to at least one of the ternary or quaternary materials: indium aluminum arsenide (InAlAs), indium gallium arsenide (InGaAs), Indium gallium arsenide phosphide (InGaAsP), or indium gallium aluminum arsenide (InGaAlAs). These one or more layers may further be referred to as low thermal conductivity layers, as described herein, and may correspond to materials having a thermal conductivity that is less than a threshold, such as approximately 5 Wm-1K-1. Furthermore, the layers may be referred to as low thermal conductivity layers by comparison to other layers or portions of the EML. By way of example, the low thermal conductivity layers may have thermal conductivity value(s) that are less than the thermal conductivity of a substrate of the EML chip. The efficiency of the heater can be estimated by a heat flow consideration. For example, the power needed to increase the temperature by dT (ΔT) is given by Equation 1:

$$P = \frac{σ dTLW}{D} , \qquad ( 1 )$$

where sigma (σ) is the thermal conductivity of the low thermal conductivity layers, D is the layers thickness, L is the length, and W is the width of this layer. As one non-limiting example, given D=1.5 um, L=100 um, W=6 μm, and dT=1 degree C., heater power consumption can be determined as P=2 mW/deg, or heater power dissipation of about 80 mW for 40 deg C. temperature rise.

Systems and methods of the present disclosure may provide an EML with a local heater, which may also be referred to as an integrated local heater. The heater, such as a resistive heater, may be located in a vicinity of the modulator section of the EML, and is designed to heat the modulator but not to significantly or appreciably heat the substrate and the laser part of the chip. The heater may be used to address detuning with EMLs. Detuning is an important parameter associated with the EML design as explained herein. Optical modulation in Indium Phosphide (InP) EAMs is based on the quantum confined stark effect (QCSE) in multiple quantum wells (MQW) layer stack located between epitaxially grown n-type and p-type InP cladding layers, forming an intrinsic (i) region in a p-i-n junction. The MQW stack also forms the core of the optical waveguide of the modulator. The absorption edge wavelength of a particular MQW stack can be defined (for example) as the optical wavelength associated with the energy bandgap of the MQW material. When electrical field is applied the optical absorption edge is shifted towards longer wavelengths due to the QCSE effect. The absorption edge shift in the EAM due to the applied voltage provides a change in the absorption coefficient, resulting in the modulation of the optical signal that is propagating along the optical waveguide of the EAM.

The difference between the absorption edge wavelength and the laser wavelength at a given temperature, is defined as the wavelength detuning of the EML. It is well known in the previous art that for optimized operation of the EML the wavelength detuning must be constrained. For optimized EML operation at the O-band wavelength range (1260-1360 nm), the detuning should typically be in the range of 40-60 nm, such as in X. Dai et al., “Versatile externally modulated lasers technology for multiple telecommunication applications”, Journal of Selected Topics in Quantum Electronics, Vol. 27, Issue 3, May-June 2021. The reason for this constraint is that if the detuning is too large, there is a drop in modulation efficiency (e.g., the amount of optical extinction for a given modulation voltage). On the other hand, if the detuning is too small the insertion loss of the modulator is severely increased. The detuning depends on temperature and becomes non-optimal in conventional uncooled EMLs when the ambient temperature range is too high. Systems and methods of the present disclosure enable detuning control over ambient temperature, and thus enable an increase in ambient temperature range without increasing the detuning range. It is well known that the laser wavelength shift with temperature is very small, compared to the modulator wavelength shift. Therefore, the heater may be deployed when the ambient temperature drops, to keep the EML at optimal detuning. The heater is efficiently coupled to the modulator waveguide, without appreciably applying the heat to the laser waveguide through the common substrate. In this way, the laser performance is not degraded by the operation of the heater, but the EML detuning range can be reduced, even when the ambient temperature varies over a large temperature range.

Variations of this and other such functionality can be used as well within the scope of the various embodiments as would be apparent to one of ordinary skill in the art in light of the teachings and suggestions contained herein.

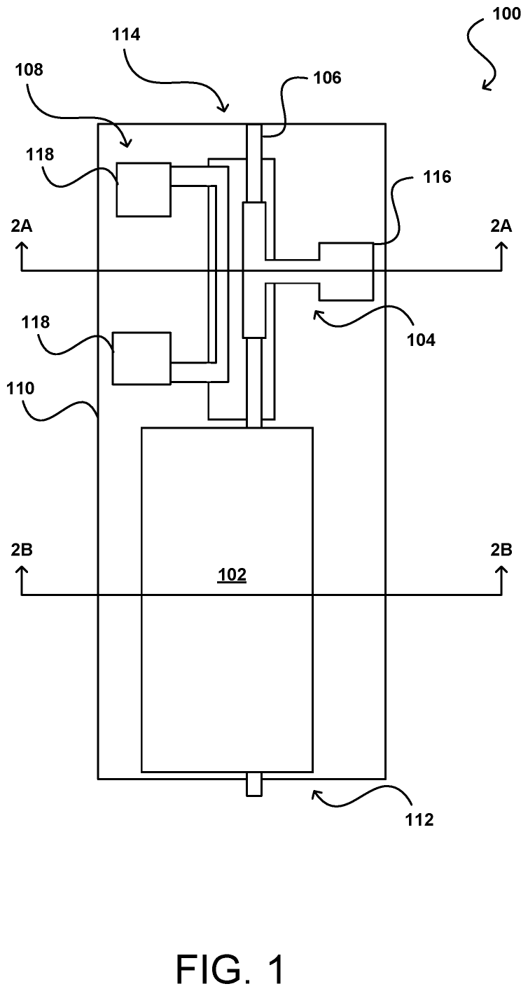

FIG. 1 illustrates a top view of an embodiment of an electro-absorption modulated laser 100 (EML), that may be used with embodiments of the present disclosure. This example includes a laser region 102 and a modulator region 104. The laser region 102 may include a laser (e.g., a laser diode) operable to emit light responsive to an input (e.g., current, voltage, etc.). An optical waveguide 106 extends between the laser region 102 and the modulator region 104. In certain embodiments, the optical waveguide 106 and/or portions thereof may be referred to with respect to the modulator and/or the laser. That is, embodiments may describe a portion of the optical waveguide 106 as the modulator waveguide and a portion of the optical waveguide 106 as the laser waveguide based on relative positions with respect to the laser region 102 and/or the modulator region 104.

Systems and methods of the present disclosure incorporate a heat generating element 108 (e.g., heat generating unit, heater, resistive heater, etc.) onto a chip 110 incorporating the EML 100. In other words, the heat generating element 108 may be integrally formed with the EML 100 (e.g., as part of the semiconductor chip and/or layers deposited on a top surface at a desired location). Heat is generated by applying voltage or current to the heat generating element 108 through electrical pads 118. In at least one embodiment, the heat generating element 108 is particularly arranged to provide heat energy preferentially to the modulator region 104. For example, the laser region 102 may be at least partially thermally isolated from the heat generating element 108 such that a portion of heat generation provided to the modulator region 104 is greater than residual heat that is applied to the laser region 102.

Embodiments of the present disclosure are provided by way of example as illustrated in FIG. 1. It should be appreciated that different chip configurations may be presented within the scope of the disclosure. In this example, the chip 110 may be sized based on a variety of factors, including manufacturing costs, operational requirements, and the like. This example may include the chip 110 having dimensions of approximately 700 μm length, approximately 300 μm width, and approximately 100 μm thickness. Different configurations may have different sizes while still incorporating the features and benefits described herein. The modulator may include one or more electrodes that receive a signal (e.g., rf drive signal) through modulator pads 116. The heater 108 in this example may include a layer formed from a high resistivity metal, such as nichrome (NiCr) as one non-limiting example, to generate heat that is absorbed by the modulator.

Various embodiments of the present disclosure may describe the chip 110 as including the laser region 102 at a first end 112 and the modulator region 104, along with the heater 108, at a second end 114, which is opposite the first end 112. The arrangement of these components may provide for spatial separation contributing to thermal isolation, that enable localized heating of the modulator region 104 without significantly increasing a temperature of the substrate and of the laser region 102. That is, the heater 108 may be considered to be thermally well isolated from the laser region 102.

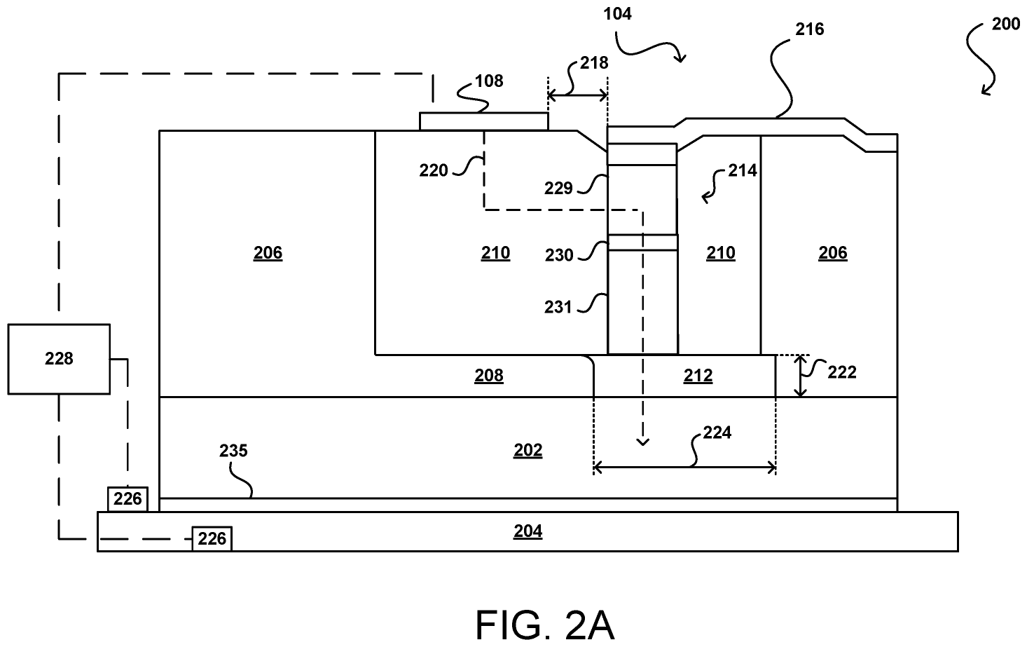

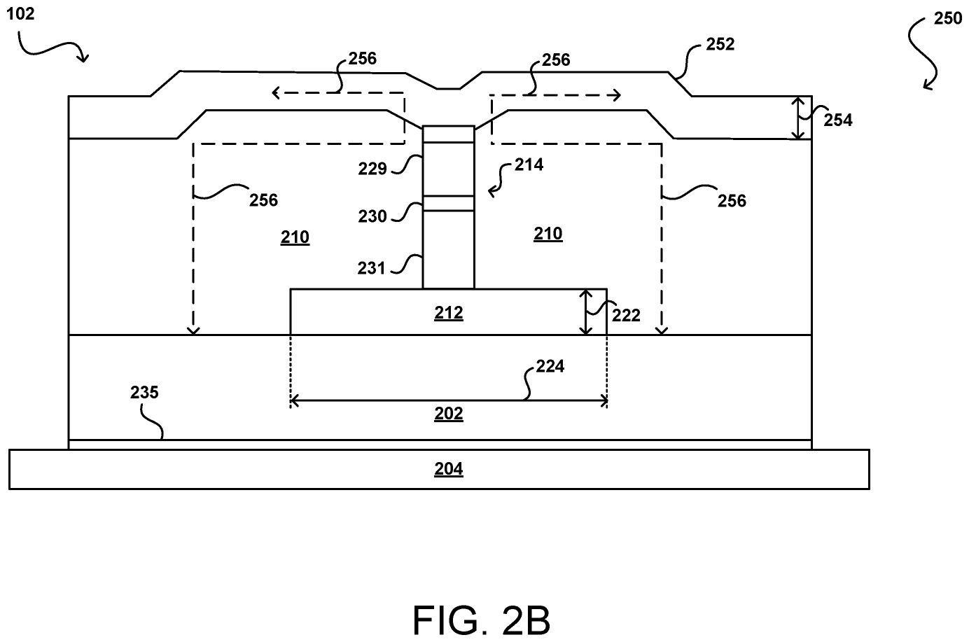

FIG. 2A illustrates a cross-sectional view of the modulator region 104 taken along line 2A-2A. An EAM 200 (e.g., a chip) is formed on a substrate 202, which may be formed from materials such as, but not limited to, indium phosphide (InP) or gallium arsenide (GaAs) or silicon (Si). In at least one embodiment, the substrate 202 is doped with an n-type dopant, which may then be referred to as an n-InP substrate.

The illustrated substrate 202 is arranged on a heat sink 204 in this example, which may be some form of carrier for the chip. As mentioned previously, the EAM waveguide 214 (e.g., modulator p-i-n junction, laser p-i-n junction, p-i-n layers, laser junction, etc.) is composed of semiconductor materials forming a p-i-n junction. The intrinsic (i) region is an undoped MQW stack 230 located between p-doped InP 229 and n-doped InP 231 cladding layers. These layers may be surrounded by a semiconductor material 210 that may be for example semi-insulating InP (SI-InP) layer iron (Fe) doped. Electrical rf signal is fed into the anode of the modulator junction by means of a modulator contact pad 216 (e.g., metal pad electrode). A low thermal conductivity layer 212 is n-doped, located on the n-substrate 202. The cathode (ground) contact to the p-i-n junction is shown as a metal electrode 235 located at the back side of the chip 200.

The semiconductor material 210 of the EAM may be encapsulated or otherwise at least partially surrounded by a polymer layer 206 (e.g., a polymer region, a spacing layer), which may be benzocyclobutene (BCB), polyimide (PI), or other thermally insulating material. The polymer layer 206 may extend from the modulator contact pad 216 to the substrate 202. In this example, the polymer layer 206 may include an undercut region 208 in the semiconductor material 210, and may be used to separate portions of the EAM from the substrate 202 and/or to direct heat transfer toward a particular region of the substrate 202. In other words, at least a portion of the polymer layer 206 may be positioned to reduce the heat flow from the modulator region to the substrate 202.

Embodiments of the present disclosure further incorporate the illustrated heat generating element 108 along the surface of the chip 200. In this example, the heat generating element 108 is positioned over the semiconductor material 210 and within a distance 218 of the modulator p-i-n junction 214. In at least one embodiment, the distance 218 is particularly selected to be small and limited by manufacturing process tolerances and capabilities. As discussed herein, the heat generating element 108 may be an electrical resistance heater in one or more embodiments and may include or have layers from electrically resistive materials, including but not limited to, NiCr, Platinum, titanium, or combinations thereof. The line 220 illustrates an example heat flow path responsive to an input current applied to the heat generating element 108.

Systems and methods may further vary a “size” (e.g., a height, a width, a length, an area, a volume, etc.) of the low thermal conductivity layer 212 and/or associated components based on one or more properties of the chip and intended operating conditions. For example, the illustrated low thermal conductivity layer 212 has a thickness 222 and a width 224 in the illustrated embodiment. One or both of the thickness 222 and/or the width 224 may be changed to modify different heat transfer properties of the modulator.

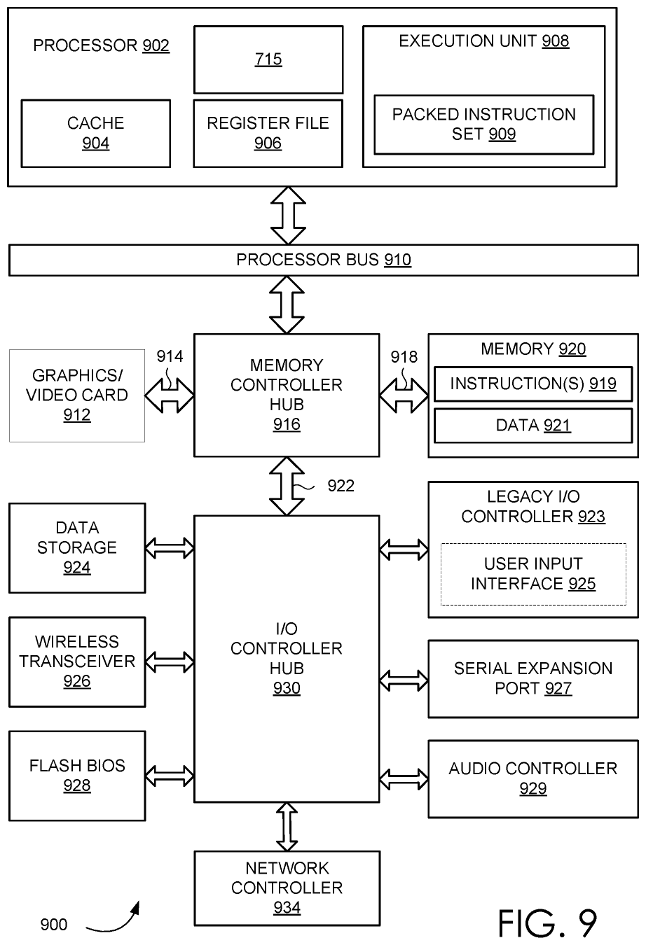

In at least one embodiment, one or more thermal sensor(s) 226 may be positioned on or within the heat sink 204. The thermal sensors 226 may also be arranged at various other locations and the positions shown in FIG. 2A are provided by non-limiting example. The thermal sensors may be used to determine one or both of a temperature of the heat sink 204 and/or an ambient temperature of an environment associated with the EML. A control circuit may be used to regulate the power dissipation. The thermal sensor(s) may be communicatively coupled to a controller 228 that may be used to send a signal to the heat generating element 108 (and/or a controller or input thereof) to adjust the electrical power dissipation according to variations in the ambient temperature. In one or more embodiments, the control circuit and/or the controller may refer to computer systems, local microprocessors, or integrated circuits (ICs). The illustrated control circuit may use or be part of other control systems associated with different EML operational parameters, such as bias voltage, laser current, etc. Accordingly, the controller 228 may refer to one or more different control devices that can be used to adjust one or more operational parameters and descriptions of full computer systems, such as those in FIG. 9, are provided by way of non-limiting example.

FIG. 2B illustrates a cross-sectional view of the laser region 102 taken along line 2B-2B. In this example, a laser p-i-n junction 214 is illustrated arranged over the substrate 202, which is mounted to the heat sink 204. In this example, the semiconductor material 210 is arranged around the p-i-n layers 214. Additionally, the low thermal conductivity layer 212 may be positioned between the p-i-n layers 214 and the substrate 202, and may be reduced in width 224 so it does not hinder heat conduction from the laser junction 214 to the substrate.

Various embodiments may further provide for heat dissipation by way of the laser anode contact pad 252 located mostly over the semiconductor material 210 surrounding the laser junction 214. For example, in at least one embodiment, a thickness 254 of the pad 252 may be approximately 1.5 μm, or the laser pad 252 may be thicker, which may facilitate dissipating heat horizontally across a top surface of the laser 250. In one or more embodiments, the laser pad contact 252 may be formed from a combination of thick, highly heat conducting metals such as, but not limited to, at least one of Au, Pt, Ti, Ag, or Al. The heat flow path 256 shows schematically how heat spreading through the heat flow path 256 and the surrounding semiconductor material 210 may facilitate heat flow from the laser junction 214 to the substrate 202 and thus reduce the laser operating temperature and reduce the laser power consumption.

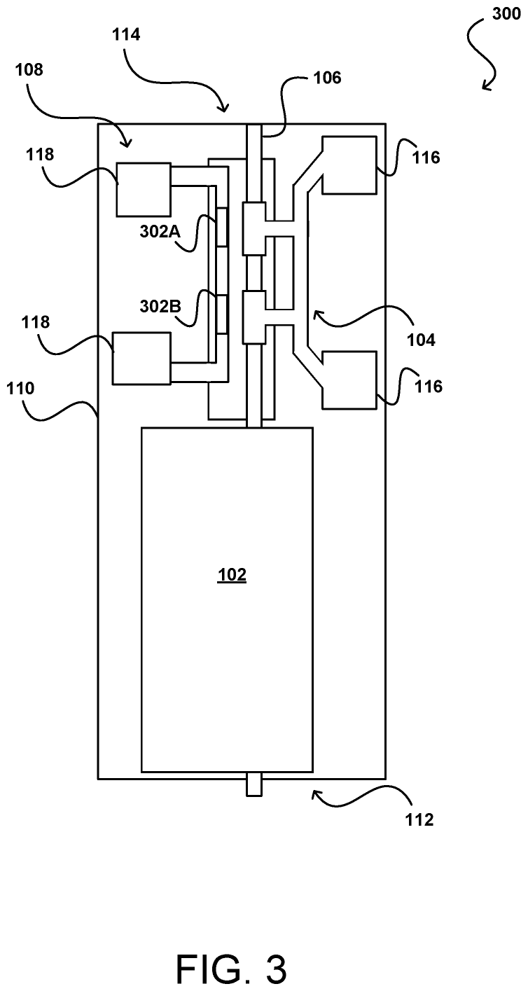

FIG. 3 is showing a top view of a segmented EAM 300 with an integrated segmented resistive heater. For increasing the modulator bandwidth it is possible to use segmented EAMs. The use of these devices for high speed travelling wave electro-absorption modulators (TWEAM's) have been well documented in the previous art, such as in G. L. Li et al., “Analysis of Segmented Traveling-Wave Optical Modulators”, Journal of Lightwave Technology, Vol. 22, No. 7, July 2004. For segmented EAMs, embodiment of this disclosure demonstrate the use of integrated segmented heaters 302, as shown in FIG. 3. In this figure, the heat generating element 108 is divided into segments 302A, 302B located in close proximity to the active modulator segments. This may be useful for not heating the passive waveguide sections between the active modulator segments, thus reducing the heater power consumption and increasing its efficiency.

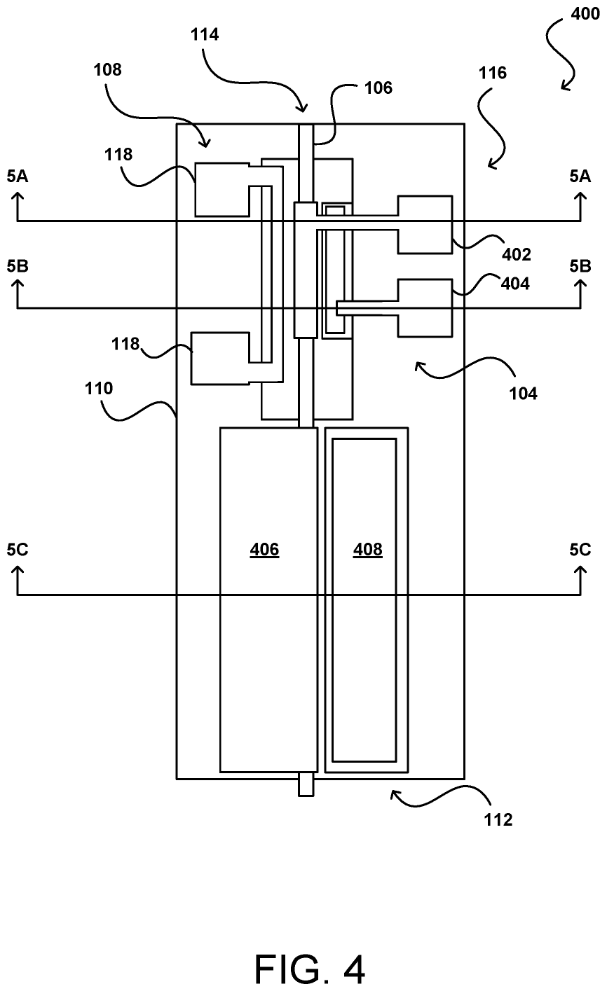

FIG. 4. illustrates a top view of differential EML 400 with the integrated resistive heater 108. Currently, most EMLs that are deployed are single ended devices. However, differential EAM devices have also been proposed using silicon photonics technology, such as in J. Fujikata et al., “High-speed Ge/Si electro-absorption optical modulator in C-band operation wavelengths”, Optics Express, Vol. 28, No. 22/26 Oct. 2020. Differential EMLs are highly desirable for data center applications, as differential rf signaling is often being employed by the serializer/deserializer (SerDes) integrated circuits pervasively deployed in data centers. The common use of differential rf signals in data centers is due to its numerous advantages such as double signal voltage, common mode and supply noise rejection, better cross talk immunity, and potential for higher bandwidth. One major distinction of differential EMLs is the use of SI (semi-insulating) substrate. For these modulators it is necessary to locate both the anode and cathode electrode contacts of the EAM and the laser on the top side of the chip.

The illustrated EML 400 may share one or more components with the EMLs discussed herein with respect to FIGS. 1, 2A, and 2B, such as the laser region 102, the modulator region 104, the optical waveguide 106, and the like. Additionally illustrated is the integrated resistive heater 108 including the electrical pads 118. This example illustrates the modulator pads 116 including both a modulator pad anode 402 and a modulator pad cathode 404. Further illustrated in FIG. 4 is the laser region 102 including a laser pad anode 406 and a laser pad cathode 408. In this example, the optical waveguide is shown as being aligned with the laser pad anode 406.

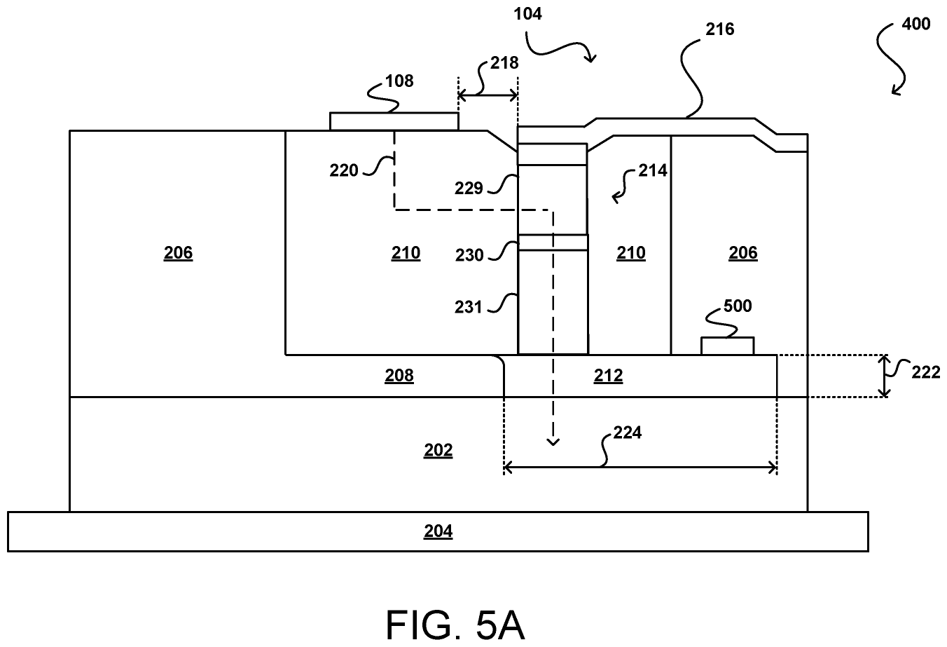

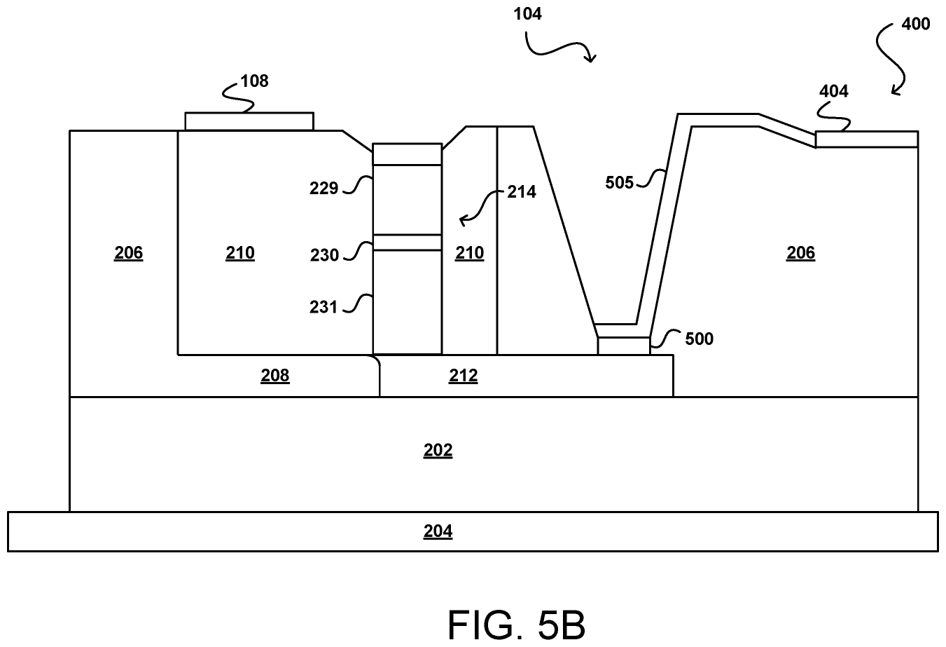

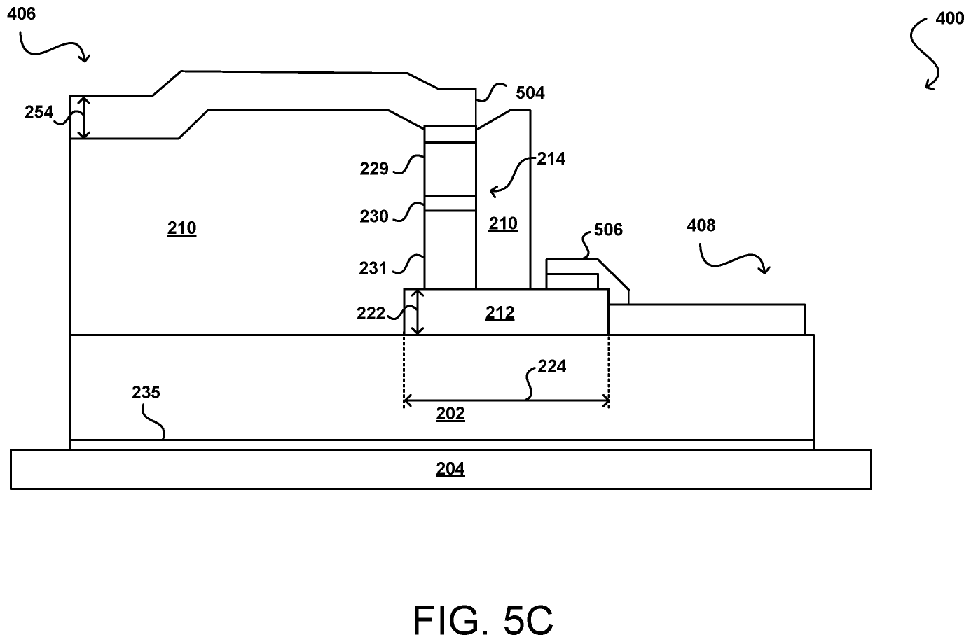

FIG. 5A shows a cross section 5A-5A through the anode contact of the differential EAM. In this example, a cathode contact metal layer 500 (e.g., contact metal layer, metal layer, etc.) is located on the cathode layer 212 and beneath the polymer layer 206. The cathode contact metal layer 500 is electrically connected to the modulator pad cathode 404 as shown in FIG. 5B.

FIG. 5B shows a cross section 5B-5B through the cathode contact of the differential EAM. In this example, the cathode contact metal layer 500 is connected to the modulator pad cathode 404 with a metal layer 505 (e.g., a metal trace) through a via hole in the polymer layer 206.

It should be noted that the low thermal conductivity layer (or combination of layers) 212 is doped n-type, and leads to the cathode contacts of the EAM and of the laser. As discussed herein, several features may be shared between embodiments, such as the components used in FIGS. 2A and 5A. However, in this example, the lower thermal layer 212 may have a different width 224 when compared to the embodiment of FIG. 2A and, in this example, the lower thermal layer 212 also supports the cathode contact metal layer 500. The modulator pad cathode 404 is positioned on the polymer layer 206. Additionally, this example includes a recessed area within the polymer layer 206 such as to allow the modulator pad cathode 404 to be electrically connected with cathode contact metal layer 500 by means of the metal trace 505.

FIG. 5C illustrates a cross section 5C-5C through the laser of the differential EML. The laser region 102 including the laser pad anode 406 and the laser pad cathode 408. In this example, the laser pad anode 406 extends to an anode contact 504. Further illustrated is a laser cathode contact 506 connected with a metal layer 506 to the laser cathode pad 408 positioned above the substrate 202. The laser pad anode 406 is positioned above the semiconductor material 210, to provide high thermal conductivity to the substrate 202.

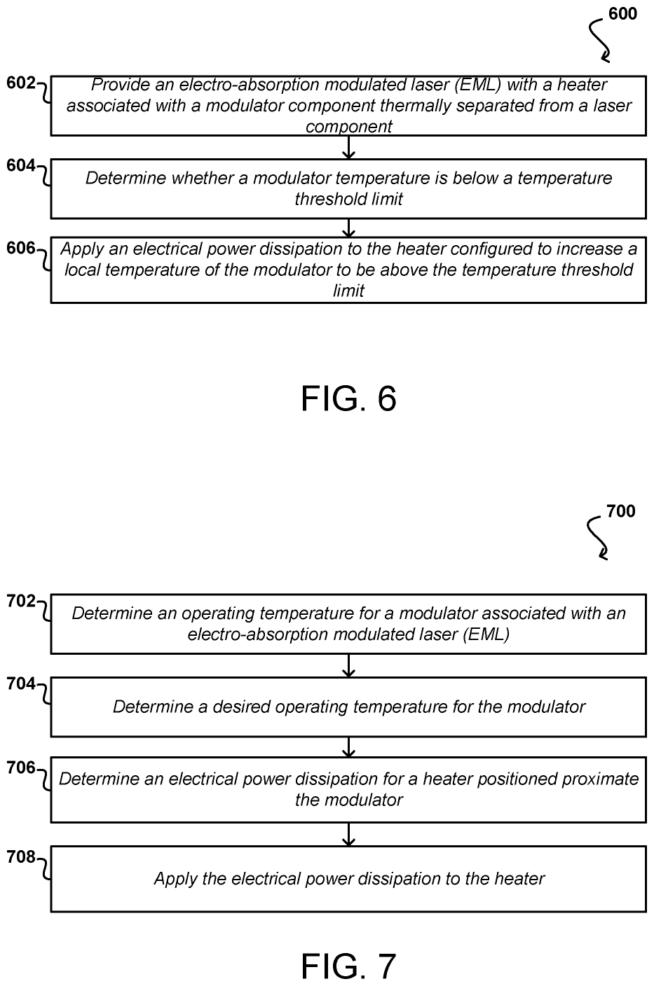

FIG. 6 illustrates an example process 600 that can be used to increase a local modulator temperature in accordance with various embodiments. It should be understood that for this and other processes presented herein that there may be additional, fewer, or alternative operations performed in similar or alternative orders, or at least partially in parallel, within the scope of the various embodiments unless otherwise specifically stated. Further, while this example refers to EAM and laser components, it should be understood that various other components may also use such a process within the scope of various embodiments. In this example, an EML with a heater is provided 602. The heater may be an electrical resistance heater positioned proximate a modulator of the EML. In at least one embodiment, one or more thermally insulating components, such as layers, may be used to at least partially isolate the heater from the substrate.

The modulator temperature of the EML may be determined to below a modulator temperature threshold limit 604. In one or more embodiments, the modulator temperature may be, at least in part, affected by an environmental temperature. The environmental temperature may be between 20 and 80 degrees C., as discussed herein, and in various embodiments may be set or otherwise within a range defined by one or more standards organizations. In at least one embodiment, one or more sensors may be used to determine the environmental temperature. The sensors may be associated with the EML, such as positioned on a heat sink, or may be separate sensors that provide information to one or more controllers associated with the EML. An electrical power dissipation may be applied to the heater to increase a local temperature of the modulator 606. For example, a current may be applied to the heater to generate heat that is absorbed by the modulator, thereby increasing the operating temperature of the modulator above the temperature threshold limit.

FIG. 7 illustrates an example process 700 to activate a local heating source for a modulator associated with an EML that may be used with embodiments of the present disclosure. In this example, an operating temperature for a modulator associated with an EML is determined 702. The modulator temperature may be determined by a heat flow calculation based on the environment heat sink temperature, the heater power dissipation, and the thermal conductivities and dimensions of the layers surrounding the modulator. In another example, one or more tables may be used based on other information associated with the EML. A lookup table may be used to identify the temperature increase associated with the heater power dissipation and one or more operating conditions in order to infer the operating temperature of the modulator.

A desired operating temperature for the modulator may be determined 704. In at least one embodiment, a desired temperature may be at a “high” end of an anticipated environmental temperature range. The electrical power dissipation of the heater may be determined 706, such that it locally heats the modulator and causes the modulator to operate at a desired temperature, which may be within the desired modulator operating range. The electrical power dissipation may then be applied to the heater 708. Accordingly, heat may be selectively applied to the modulator in order to maintain operation within a desired modulator temperature range.

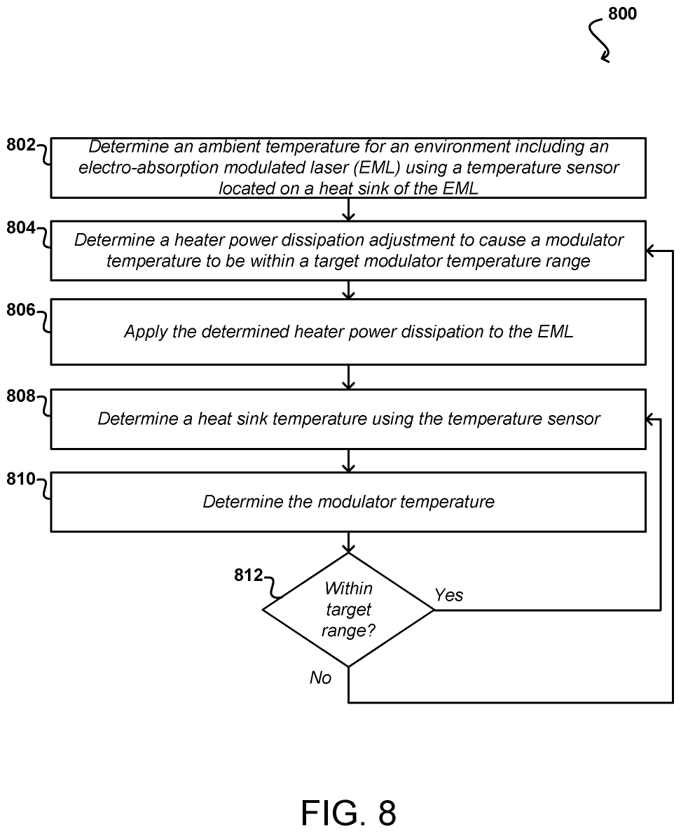

FIG. 8 illustrates an example process 800 to activate a local heating source for a modulator associated with an EML that may be used with embodiments of the present disclosure. The ambient temperature near the EML may be determined using a temperature sensor located on a heat sink of the EML 802. A heater power dissipation adjustment may be determined 804. The heater power dissipation may be an amount of dissipation to cause the modulator to operate within a target modulator temperature range. In at least one embodiment, the determined heater power dissipation is applied 806. For example, an electrical input may be provided to a heater arranged proximate a modulator of the EML. A heat sink temperature may be determined using the temperature sensor 808. Additionally, in at least one embodiment, the modulator temperature may be determined 810, for example, the modulator temperature may be calculated. The modulator temperature T (modulator) may be calculated using Equation 2:

$$T ( modulator ) = T ( heat sink ) + \frac{σ PD}{LW} , \qquad ( 2 )$$

which is derived from Equation 1. Here, T (heat sink) is the measured temperature of the heat sink using a temperature sensor located on the heat sink near the EML. In another example the modulator temperature may be calculated using similar heat flow equations according to the different thermal conductivities and dimensions of the modulator and surrounding layers and the substrate. The modulator temperature may also be determined by using a look-up table to identify the temperature increase associated with the heater power dissipation and one or more additional operating conditions associated with the operation of the EML. The determined modulator temperature may then be used to determine whether the modulator temperature is within the target range 812. If not, then another heater power dissipation adjustment may be calculated. If so, then the heat sink temperature may be continuously measured and monitored.

### Computer Systems

FIG. 9 is a block diagram illustrating an exemplary computer system 900, which may be a system with interconnected devices and components, a system-on-a-chip (SOC) or some combination thereof formed with a processor that may include execution units to execute an instruction, according to at least one embodiment. In at least one embodiment, computer system 900 may include, without limitation, a component, such as a processor 902 to employ execution units including logic to perform algorithms for process data, in accordance with present disclosure, such as in embodiment described herein. In at least one embodiment, computer system 900 may include processors, such as PENTIUM® Processor family, Xeon™, Itanium®, XScale™ and/or StrongARM™, Intel® Core™, or Intel® Nervana™ microprocessors available from Intel Corporation of Santa Clara, California, although other systems (including PCs having other microprocessors, engineering workstations, set-top boxes and like) may also be used. In at least one embodiment, computer system 900 may execute a version of WINDOWS' operating system available from Microsoft Corporation of Redmond, Wash., although other operating systems (UNIX and Linux for example), embedded software, and/or graphical user interfaces, may also be used.

Embodiments may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (“DSP”), system on a chip, network computers (“NetPCs”), set-top boxes, network hubs, wide area network (“WAN”) switches, or any other system that may perform one or more instructions in accordance with at least one embodiment.

In at least one embodiment, computer system 900 may include, without limitation, processor 902 that may include, without limitation, one or more execution units 908 to perform machine learning model training and/or inferencing according to techniques described herein. In at least one embodiment, computer system 900 is a single processor desktop or server system, but in another embodiment computer system 900 may be a multiprocessor system. In at least one embodiment, processor 902 may include, without limitation, a complex instruction set computing (“CISC”) microprocessor, a reduced instruction set computing (“RISC”) microprocessor, a very long instruction word (“VLIW”) computing microprocessor, a processor implementing a combination of instruction sets, or any other processor device, such as a digital signal processor, for example. In at least one embodiment, processor 902 may be coupled to a processor bus 910 that may transmit data signals between processor 902 and other components in computer system 900.

In at least one embodiment, processor 902 may include, without limitation, a Level 1 (“L1”) internal cache memory (“cache”) 904. In at least one embodiment, processor 902 may have a single internal cache or multiple levels of internal cache. In at least one embodiment, cache memory may reside external to processor 902. Other embodiments may also include a combination of both internal and external caches depending on particular implementation and needs. In at least one embodiment, register file 906 may store different types of data in various registers including, without limitation, integer registers, floating point registers, status registers, and instruction pointer register.

In at least one embodiment, execution unit 908, including, without limitation, logic to perform integer and floating point operations, also resides in processor 902. In at least one embodiment, processor 902 may also include a microcode (“ucode”) read only memory (“ROM”) that stores microcode for certain macro instructions. In at least one embodiment, execution unit 908 may include logic to handle a packed instruction set 909. In at least one embodiment, by including packed instruction set 909 in an instruction set of a general-purpose processor 902, along with associated circuitry to execute instructions, operations used by many multimedia applications may be performed using packed data in a general-purpose processor 902. In one or more embodiments, many multimedia applications may be accelerated and executed more efficiently by using full width of a processor's data bus for performing operations on packed data, which may eliminate need to transfer smaller units of data across processor's data bus to perform one or more operations one data element at a time.

In at least one embodiment, execution unit 908 may also be used in microcontrollers, embedded processors, graphics devices, DSPs, and other types of logic circuits. In at least one embodiment, computer system 900 may include, without limitation, a memory 920. In at least one embodiment, memory 920 may be implemented as a Dynamic Random Access Memory (“DRAM”) device, a Static Random Access Memory (“SRAM”) device, flash memory device, or other memory device. In at least one embodiment, memory 620 may store instruction(s) 919 and/or data 921 represented by data signals that may be executed by processor 902.

In at least one embodiment, system logic chip may be coupled to processor bus 910 and memory 920. In at least one embodiment, system logic chip may include, without limitation, a memory controller hub (“MCH”) 916, and processor 902 may communicate with MCH 916 via processor bus 910. In at least one embodiment, MCH 916 may provide a high bandwidth memory path 918 to memory 920 for instruction and data storage and for storage of graphics commands, data and textures. In at least one embodiment, MCH 916 may direct data signals between processor 902, memory 920, and other components in computer system 900 and to bridge data signals between processor bus 910, memory 920, and a system I/O 922. In at least one embodiment, system logic chip may provide a graphics port for coupling to a graphics controller. In at least one embodiment, MCH 916 may be coupled to memory 920 through a high bandwidth memory path 918 and graphics/video card 912 may be coupled to MCH 616 through an Accelerated Graphics Port (“AGP”) interconnect 914.

In at least one embodiment, computer system 900 may use system I/O 922 that is a proprietary hub interface bus to couple MCH 916 to I/O controller hub (“ICH”) 930. In at least one embodiment, ICH 930 may provide direct connections to some I/O devices via a local I/O bus. In at least one embodiment, local I/O bus may include, without limitation, a high-speed I/O bus for connecting peripherals to memory 920, chipset, and processor 902. Examples may include, without limitation, an audio controller 929, a firmware hub (“flash BIOS”) 928, a wireless transceiver 926, a data storage 924, a legacy I/O controller 923 containing user input and keyboard interfaces 925, a serial expansion port 927, such as Universal Serial Bus (“USB”), and a network controller 934. Data storage 924 may comprise a hard disk drive, a floppy disk drive, a CD-ROM device, a flash memory device, or other mass storage device.

In at least one embodiment, FIG. 9 illustrates a system, which includes interconnected hardware devices or “chips”, whereas in other embodiments, FIG. 9 may illustrate an exemplary System on a Chip (“SoC”). In at least one embodiment, devices may be interconnected with proprietary interconnects, standardized interconnects (e.g., PCIe) or some combination thereof. In at least one embodiment, one or more components of computer system 900 are interconnected using compute express link (CXL) interconnects.

Inference and/or training logic 715 are used to perform inferencing and/or training operations associated with one or more embodiments. In at least one embodiment, inference and/or training logic 715 may be used in system FIG. 9 for inferencing or predicting operations based, at least in part, on weight parameters calculated using neural network training operations, neural network functions and/or architectures, or neural network use cases described herein.

Various embodiments can be described by the following clauses:

1. A system, comprising:
a substrate;
a semiconductor laser, located on the substrate, configured to generate light;
a modulator, located on the substrate, configured to receive the light from the laser and modulate an intensity of the light; and
a heat generating element positioned proximate the modulator.

2 The system of clause 1, further comprising:
a layer having low thermal conductivity properties underlying the modulator and positioned between the modulator and the substrate.

3. The system of clause 2, wherein the substrate is at least one of indium phosphide (InP) or gallium arsenide (GaAs) or silicon (Si), and the layer is comprised of at least one of indium aluminum arsenide (InAlAs), indium gallium arsenide (InGaAs), indium gallium arsenide phosphide (InGaAsP), or indium gallium aluminum arsenide (InGaAlAs).

4. The system of clause 2, further comprising:
a thermal insulation layer at least partially surrounding the layer, wherein the thermal insulation layer includes at least one of a polymer or air.

5. The system of clause 2, wherein a first thermal conductivity of the layer is less than a second thermal conductivity of the substrate.

6. The system of clause 2, where the layer having low thermal conductivity is undercut beneath a semiconductor material surrounding the modulator to reduce an area of the layer having low thermal conductivity and to reduce heat conduction through the layer having low thermal conductivity.

7. The system of clause 6, wherein an undercut region below the semiconductor modulator material is at least partially filled with a thermally insulating polymer material.

8. The system of clause 1, further comprising:
a polymer region associated with the modulator, the polymer region extending from a modulator contact pad to the substrate and at least partially encapsulating the modulator.

9. The system of clause 8, wherein at least a portion of the polymer region is positioned to reduce heat flow from the modulator to the substrate.

10. The system of clause 1, wherein the heat generating element comprises an electric resistive heater.

11. The system of clause 1, further comprising:
a heat sink supporting the substrate;
a temperature sensor located on the heat sink; and
a control circuit coupled to the heat generating element, wherein the control circuit is configured to adjust an electrical power dissipation of the heat generating element according to variations in an ambient temperature measured by the temperature sensor.

12. The system of clause 1, wherein the system is an electro-absorption modulated laser.

13. An electro-absorption modulated laser (EML) formed on a substrate, comprising:
a laser, arranged at a first end of the substrate, configured to generate light;
a modulator, arranged at a second end of the substrate and aligned with the laser, configured to receive the light and modulate an intensity of the light responsive to an input voltage; and
a heater arranged at the second end of the substrate, the heater being thermally insolated with respect to the laser.

14. The EML of clause 13, wherein laser has higher first thermal conductivity to the substrate compared to a second thermal conductivity to the substrate of the modulator.

15. The EML of clause 13, further comprising:
an electrode associated with the laser having a thickness greater than 1.5 μm.

16. The EML of clause 15, wherein the electrode is made of a combination of at least one of gold (Au), Platinum (Pt), Titanium (Ti), Silver (Ag), and Aluminum (Al).

17. The EML of clause 13, wherein where the substrate is n-type indium phosphide (InP) and the modulator is a single ended electro-absorption modulator.

18. The EML of clause 13, where the substrate is semi-insulating indium phosphide (InP) and the modulator is a differential electro-absorption modulator.

19. A method, comprising:
providing an electro-absorption modulated laser (EML) with a heater associated with a modulator component and thermally separated from a laser component;
determining whether the environmental temperature for an area containing the EML is below a given temperature threshold; and
applying an electrical power dissipation to the heater configured to increase a local temperature of the modulator.

20 The method of clause 19, wherein a temperature of a laser associated with the EML is not significantly increased responsive to the electrical power dissipation of the heater.

21. The method of clause 19, comprising:
causing an operating temperature of the modulator to increase, responsive to the electrical power dissipation of the heater, to a value at a higher end of an ambient temperature range.

22. The method of clause 19, wherein the ambient temperature range is approximately 20-80 degrees C., the given temperature threshold value is approximately 60 degrees C., the electrical power dissipation of the heater is below 100 mW, and a modulator temperature range, responsive to the electrical power dissipation of the heater is between 60-80 degrees C.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. Term “connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. Use of term “set” (e.g., “a set of items”) or “subset,” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B, and at least one of C each to be present. In addition, unless otherwise noted or contradicted by context, term “plurality” indicates a state of being plural (e.g., “a plurality of items” indicates multiple items). A plurality is at least two items, but can be more when so indicated either explicitly or by context. Further, unless stated otherwise or otherwise clear from context, phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause computer system to perform operations described herein. A set of non-transitory computer-readable storage media, in at least one embodiment, comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors—for example, a non-transitory computer-readable storage medium store instructions and a main central processing unit (“CPU”) executes some of instructions while a graphics processing unit (“GPU”) executes other instructions. In at least one embodiment, different components of a computer system have separate processors and different processors execute different subsets of instructions.

Accordingly, in at least one embodiment, computer systems are configured to implement one or more services that singly or collectively perform operations of processes described herein and such computer systems are configured with applicable hardware and/or software that enable performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to practice of disclosure.

All references, including publications, patent applications, and patents, cited herein are hereby incorporated by reference to same extent as if each reference were individually and specifically indicated to be incorporated by reference and were set forth in its entirety herein.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, “processor” may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. Terms “system” and “method” are used herein interchangeably insofar as system may embody one or more methods and methods may be considered a system.

In present document, references may be made to obtaining, acquiring, receiving, or inputting analog or digital data into a subsystem, computer system, or computer-implemented machine. Obtaining, acquiring, receiving, or inputting analog and digital data can be accomplished in a variety of ways such as by receiving data as a parameter of a function call or a call to an application programming interface. In some implementations, process of obtaining, acquiring, receiving, or inputting analog or digital data can be accomplished by transferring data via a serial or parallel interface. In another implementation, process of obtaining, acquiring, receiving, or inputting analog or digital data can be accomplished by transferring data via a computer network from providing entity to acquiring entity. References may also be made to providing, outputting, transmitting, sending, or presenting analog or digital data. In various examples, process of providing, outputting, transmitting, sending, or presenting analog or digital data can be accomplished by transferring data as an input or output parameter of a function call, a parameter of an application programming interface or interprocess communication mechanism.

Although discussion above sets forth example implementations of described techniques, other architectures may be used to implement described functionality, and are intended to be within scope of this disclosure. Furthermore, although specific distributions of responsibilities are defined above for purposes of discussion, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A system, comprising:
a substrate;
a semiconductor laser, located on the substrate, configured to generate light;
a modulator, located on the substrate, configured to receive the light from the laser and modulate an intensity of the light; and
a heat generating element positioned proximate the modulator.

2. The system of claim 1, further comprising:
a layer having low thermal conductivity properties underlying the modulator and positioned between the modulator and the substrate.

3. The system of claim 2, wherein the substrate is at least one of indium phosphide (InP) or gallium arsenide (GaAs) or silicon (Si), and the layer is comprised of at least one of indium aluminum arsenide (InAlAs), indium gallium arsenide (InGaAs), indium gallium arsenide phosphide (InGaAsP), or indium gallium aluminum arsenide (InGaAlAs).

4. The system of claim 2, further comprising:
a thermal insulation layer at least partially surrounding the layer, wherein the thermal insulation layer includes at least one of a polymer or air.

5. The system of claim 2, wherein a first thermal conductivity of the layer is less than a second thermal conductivity of the substrate.

6. The system of claim 2, where the layer having low thermal conductivity is undercut beneath a semiconductor material surrounding the modulator to reduce an area of the layer having low thermal conductivity and to reduce heat conduction through the layer having low thermal conductivity.

7. The system of claim 6, wherein an undercut region below the semiconductor modulator material is at least partially filled with a thermally insulating polymer material.

8. The system of claim 1, further comprising:
a polymer region associated with the modulator, the polymer region extending from a modulator contact pad to the substrate and at least partially encapsulating the modulator.

9. The system of claim 8, wherein at least a portion of the polymer region is positioned to reduce heat flow from the modulator to the substrate.

10. The system of claim 1, wherein the heat generating element comprises an electric resistive heater.

11. The system of claim 1, further comprising:
a heat sink supporting the substrate;
a temperature sensor located on the heat sink; and
a control circuit coupled to the heat generating element, wherein the control circuit is configured to adjust an electrical power dissipation of the heat generating element according to variations in an ambient temperature measured by the temperature sensor.

12. The system of claim 1, wherein the system is an electro-absorption modulated laser.

13. An electro-absorption modulated laser (EML) formed on a substrate, comprising:
a laser, arranged at a first end of the substrate, configured to generate light;
a modulator, arranged at a second end of the substrate and aligned with the laser, configured to receive the light and modulate an intensity of the light responsive to an input voltage; and
a heater arranged at the second end of the substrate, the heater being thermally insolated with respect to the laser.

14. The EML of claim 13, wherein laser has higher first thermal conductivity to the substrate compared to a second thermal conductivity to the substrate of the modulator.

15. The EML of claim 13, further comprising:
an electrode associated with the laser having a thickness greater than 1.5 μm.

16. The EML of claim 15, wherein the electrode is made of a combination of at least one of gold (Au), Platinum (Pt), Titanium (Ti), Silver (Ag), and Aluminum (Al).

17. The EML of claim 13, wherein where the substrate is n-type indium phosphide (InP) and the modulator is a single ended electro-absorption modulator.

18. The EML of claim 13, where the substrate is semi-insulating indium phosphide (InP) and the modulator is a differential electro-absorption modulator.

19. A method, comprising:
providing an electro-absorption modulated laser (EML) with a heater associated with a modulator component and thermally separated from a laser component;
determining whether the environmental temperature for an area containing the EML is below a given temperature threshold; and
applying an electrical power dissipation to the heater configured to increase a local temperature of the modulator.

20. The method of claim 19, wherein a temperature of a laser associated with the EML is not significantly increased responsive to the electrical power dissipation of the heater.

21. The method of claim 19, comprising:
causing an operating temperature of the modulator to increase, responsive to the electrical power dissipation of the heater, to a value at a higher end of an ambient temperature range.

22. The method of claim 19, wherein the ambient temperature range is approximately 20-80 degrees C., the given temperature threshold value is approximately 60 degrees C., the electrical power dissipation of the heater is below 100 mW, and a modulator temperature range, responsive to the electrical power dissipation of the heater is between 60-80 degrees C.
